(19) United States
(12) Patent Application Publication
(10) Pub. No.: US 2012/0156886 A1
(43) Pub. Date: Jun. 21, 2012

(54) SUBSTRATE PROCESSING APPARATUS, METHOD OF MANUFACTURING SUBSTRATE, AND METHOD OF MANUFACTURING SEMICONDUCTOR DEVICE

(75) Inventors: Kenji Shirako, Toyama (JP); Masanao Fukuda, Toyama (JP); Takafumi Sasaki, Toyama (JP); Yoshinori Imai, Toyama (JP); Daisuke Hara, Toyama (JP); Shuhei Saido, Toyama (JP); Koei Kuribayashi, Toyama (JP)

(73) Assignee: HITACHI KOKUSAI ELECTRIC INC., Tokyo (JP)

(21) Appl. No.: 13/331,123

(22) Filed: Dec. 20, 2011

(30) Foreign Application Priority Data
Dec. 21, 2010 (JP) 2010-284387
Feb. 23, 2011 (JP) 2011-037171

(51) Int. Cl. H01L 21/306; C01B 31/36; C23F 1/08

(52) U.S. Cl. 438/706; 156/345.33; 216/2; 257/E21.219

(57) ABSTRACT

Production efficiency of a substrate (in particular, a substrate on which a SiC epitaxial film is formed) is improved and formation of the film inside a gas supply port is suppressed. This is accomplished by a substrate processing apparatus including a reaction chamber configured to accommodate a plurality of substrates 14, a heating part installed to surround the reaction chamber and configured to heat the reaction chamber, and a first gas supply pipe 60 extending in the reaction chamber, wherein the first gas supply pipe 60 includes a first gas supply port 68 configured to inject a first gas toward the plurality of substrates 14, and first shielding walls installed at both sides of the first gas supply port to expose the first gas supply port 68, the first shielding walls extending toward the plurality of substrates 14 from the first gas supply port 68.

### CROSS-REFERENCE TO RELATED PATENT APPLICATION

This U.S. non-provisional patent application claims priority under 35 U.S.C. §119 of Japanese Patent Application No. 2010-284387, filed on Dec. 21, 2010, and No. 2011-037171, filed on Feb. 23, 2011, in the Japanese Patent Office, the entire contents of which are hereby incorporated by reference.

### BACKGROUND OF THE INVENTION

1. Field of the Invention

The present invention relates to a substrate processing apparatus, a method of manufacturing a semiconductor device and a method of manufacturing a substrate, and more particularly, to a substrate processing apparatus, a method of manufacturing a semiconductor device and a method of manufacturing a substrate including a process of forming a silicon carbide (hereinafter, referred to as SiC) epitaxial film on the substrate, or a gas supply nozzle that can be used in the substrate processing apparatus.

2. Description of the Related Art

SiC is attracting particular attention as a material for power devices. Meanwhile, compared to silicon (hereinafter, referred to as Si), SiC is known to be difficult to use in the manufacture of a crystalline substrate or device.

Here, when SiC is used to manufacture a device, a wafer, in which a SiC epitaxial film is formed on a SiC substrate, is used. Patent Document 1 discloses an example of a SiC epitaxial growth apparatus for forming a SiC epitaxial film on a SiC substrate.

As disclosed in Patent Document 1, in recent times, a typical apparatus for forming a SiC epitaxial film has a configuration in which a plurality of wafers are disposed on a planar susceptor, and a source gas is supplied from a center portion of the apparatus.

[Related Art Document]

[Patent Document 1] Japanese Patent Laid-open Publication No. 2006-196807

### SUMMARY OF THE INVENTION

However, in the typical configuration of the apparatus disclosed in Patent Document 1 having a plurality of wafers disposed on the planar susceptor, when a plurality of wafers are processed all at one time, or when a diameter of the wafers is increased in order to reduce a substrate cost, a floor area of a reaction chamber may be increased.

In order to solve this problem, an object of the present invention is to provide a substrate processing apparatus, a method of manufacturing a semiconductor device and a method of manufacturing a substrate that are capable of uniformly forming films on a plurality of substrates by SiC epitaxial film growth performed under high-temperature conditions.

According to an aspect of the present invention, there is provided a substrate processing apparatus including: a reaction chamber configured to accommodate a plurality of substrates; a heating part installed to surround the reaction chamber and configured to heat the reaction chamber; and a first gas supply pipe extending in the reaction chamber, wherein the first gas supply pipe includes: a first gas supply port configured to inject a first gas toward the plurality of substrates; and first shielding walls installed at both sides of the first gas supply port to expose the first gas supply port, the first shielding walls extending toward the plurality of substrates from the first gas supply port.

According to another aspect of the present invention, there is provided a substrate processing apparatus including: a reaction chamber configured to accommodate a plurality of substrates stacked in a longitudinal direction; a heating part installed to surround the reaction chamber and configured to heat the reaction chamber; a first gas supply pipe extending in the longitudinal direction in the reaction chamber, and including a first gas supply port configured to inject a first gas toward the plurality of substrates; a second gas supply pipe extending in the longitudinal direction in the reaction chamber, and including a second gas supply port configured to inject a second gas toward the plurality of substrates; and a third gas supply pipe installed between the first gas supply pipe and the second gas supply pipe to form a third gas stream of an inert gas between a first gas stream of the first gas injected from the first gas supply port and a second gas stream of the second gas injected from the second gas supply port.

According to still another aspect of the present invention, there is provided a method of manufacturing a semiconductor device or a method of manufacturing a substrate, including: loading into a reaction chamber a plurality of substrates stacked in a boat in a longitudinal direction; supplying a first gas from a first gas supply port included in a first gas supply pipe installed in the reaction chamber along the plurality of substrates loaded into the reaction chamber and a second gas from a second gas supply port included in a second gas supply pipe installed in the reaction chamber along the plurality of substrates loaded into the reaction chamber toward each of the plurality of substrates to form a film on each of the plurality of substrates by mixing of the first gas and the second gas while suppressing a flow of the first gas toward the second gas supply port by a shielding part; and unloading from the reaction chamber the plurality of substrates stacked in the boat having the film formed thereon.

### EFFECT OF THE INVENTION

According to the present invention, productivity can be improved.

### BRIEF DESCRIPTION OF THE DRAWINGS

FIG. 1 is a perspective view of a semiconductor manufacturing apparatus in accordance with the present invention;

FIG. 2 is a lateral cross-sectional view of a processing furnace in accordance with the present invention;

FIG. 3 is a horizontal cross-sectional view of the processing furnace in accordance with the present invention;

FIG. 4 is a block diagram showing a control configuration of the semiconductor manufacturing apparatus in accordance with the present invention;

FIG. 5 is a schematic cross-sectional view of the processing furnace and its peripheral configurations of the semiconductor manufacturing apparatus in accordance with the present invention;

FIG. 6 is a schematic cross-sectional view showing an example of a processing furnace in accordance with a first embodiment;

FIG. 7 shows views of an example of a gas supply nozzle in accordance with the first embodiment;

FIG. 8 shows views of another example of the gas supply nozzle in accordance with the first embodiment;

FIG. 9 shows views of another example of the gas supply nozzle in accordance with the first embodiment;

FIG. 10 shows views of another example of the gas supply nozzle in accordance with the first embodiment;

FIG. 11 is a schematic horizontal cross-sectional view of another example of the processing furnace in accordance with the first embodiment of the present invention;

FIG. 12 is a schematic horizontal cross-sectional view of an example of a processing furnace in accordance with a second embodiment;

FIG. 13 is a schematic horizontal cross-sectional view of another example of the processing furnace in accordance with the second embodiment;

FIG. 14 is a schematic horizontal cross-sectional view of an example of a processing furnace in accordance with a third embodiment;

FIG. 15 shows views for explaining a task in accordance with a fourth embodiment;

FIG. 16 shows views of an example of a gas supply nozzle in accordance with the fourth embodiment; and

FIG. 17 is a schematic horizontal cross-sectional view of a processing furnace in accordance with the fourth embodiment.

FIG. 18 is a flowchart of a method of manufacturing substrate or a method of manufacturing semiconductor device in accordance with the exemplary embodiment of the present invention.

### DETAILED DESCRIPTION OF PREFERRED EMBODIMENTS

Hereinafter, embodiments of the present invention will be described with reference to the accompanying drawings. In the embodiments described below, a SiC epitaxial growth apparatus, which is an example of a substrate processing apparatus, is a batch type vertical SiC epitaxial growth apparatus in which SiC wafers are arranged vertically. In addition, as the batch type vertical SiC epitaxial growth apparatus is provided, the number of SiC wafers that can be processed at a time is increased to improve throughput.

### First Embodiment

### <Entire Configuration>

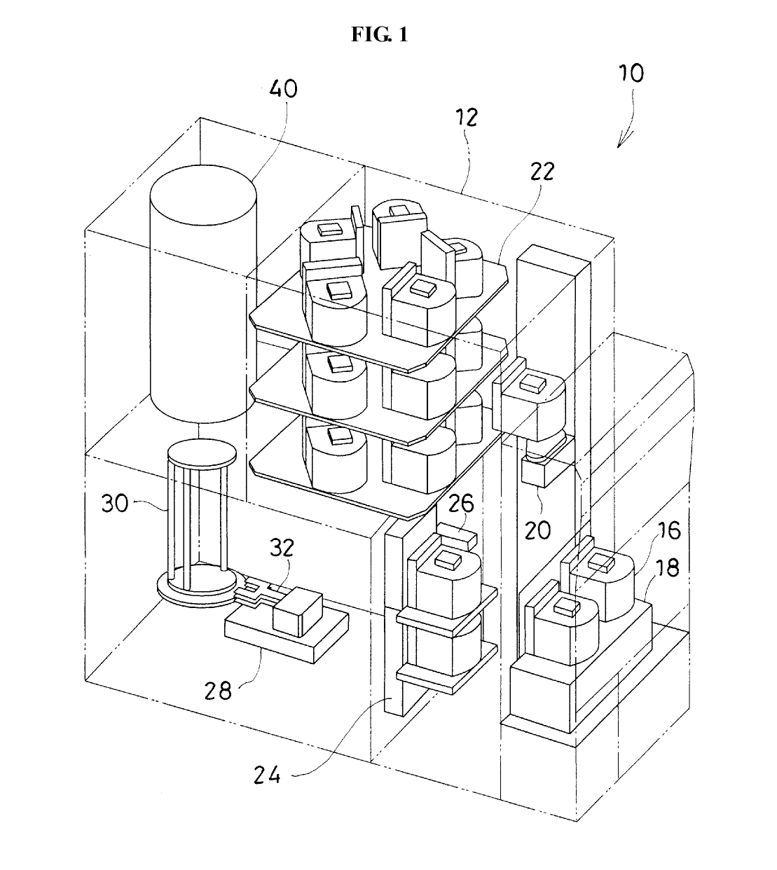

First, a substrate processing apparatus for forming a SiC epitaxial film and a method of manufacturing a substrate to form a SiC epitaxial film, one of a process of manufacturing a semiconductor device, of a first embodiment of the present invention will be described with reference to FIG. 1.

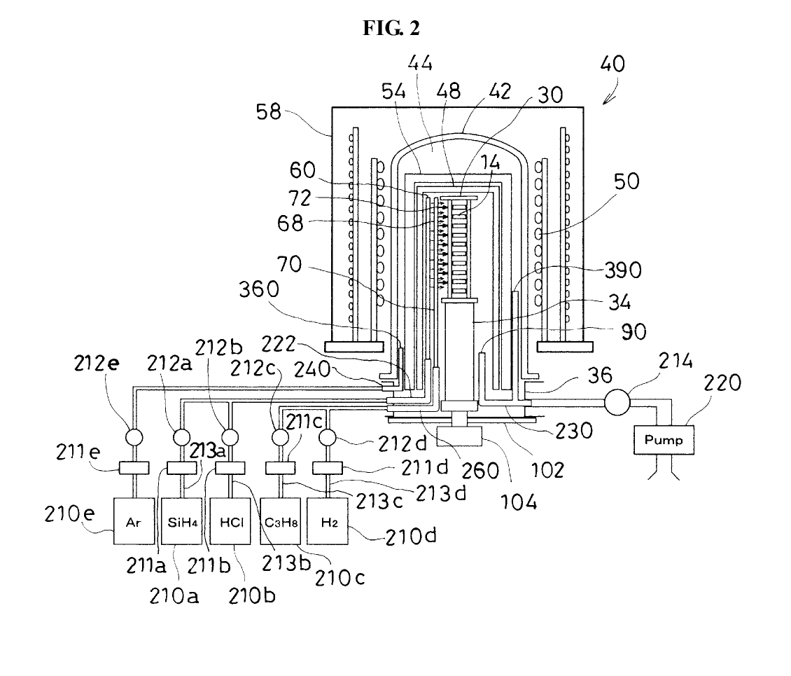

A semiconductor manufacturing apparatus 10, which is a substrate processing apparatus (a film forming apparatus), is a batch type vertical annealing apparatus, and includes a housing 12 in which major parts are disposed. In the semiconductor manufacturing apparatus 10, a front opening unified pod (FOUP, hereinafter, referred to as a pod) 16, which is a substrate-accommodating vessel configured to receive a wafer 14 (see FIG. 2), which is a substrate formed of Si, SiC, or the like, is used as a wafer carrier. A pod stage 18 is disposed in the front of the housing 12, and a pod 16 is conveyed to the pod stage 18. For example, 25 wafers 14 are received in the pod 16, and set on the pod stage 18 with a cover closed.

A pod conveyance apparatus 20 is disposed at a position in front of the housing 12 and opposite to the pod stage 18. In addition, a pod receiving shelf 22, a pod opener 24 and a substrate number detector 26 are disposed adjacent to the pod conveyance apparatus 20. The pod receiving shelf 22 is configured to be disposed over the pod opener 24 and to hold a plurality of pods 16 placed thereon. The substrate number detector 26 is disposed adjacent to the pod opener 24, and the pod conveyance apparatus 20 conveys the pod 16 between the pod stage 18, the pod receiving shelf 22 and the pod opener 24. The pod opener 24 opens a cover of the pod 16, and the substrate number detector 26 detects the number of the wafers 14 in the pod 16 with the cover open.

A substrate transfer apparatus 28 and a boat 30, which is a substrate holder, are disposed in the housing 12. The substrate transfer apparatus 28 includes an arm 32 (tweezers), and has a structure that can be elevated and rotated by a driving means (not shown). The arm 32 can extract 5 wafers 14, and the arm 32 is moved to convey the wafers 14 between the pod 16 and the boat 30 disposed at a position of the pod opener 24.

The boat 30, which is formed of a heat-resistant material such as carbon graphite or SiC, is configured to concentrically align a plurality of wafers 14 in a horizontal posture and stack and hold the wafers 14 in a longitudinal direction thereof. In addition, a boat insulating part 34, which is a disc-shaped insulating member formed of a heat-resistant material such as quartz or SiC, is disposed at a lower part of the boat 30 such that heat from an object to be heated 48 (to be described later) cannot be easily transferred to a lower side of a processing furnace 40 (see FIG. 2).

The processing furnace 40 is disposed at a rear upper portion in the housing 12. The boat 30 in which the plurality of wafers 14 are charged is loaded into the processing furnace 40 and annealed.

### <Configuration of Processing Furnace>

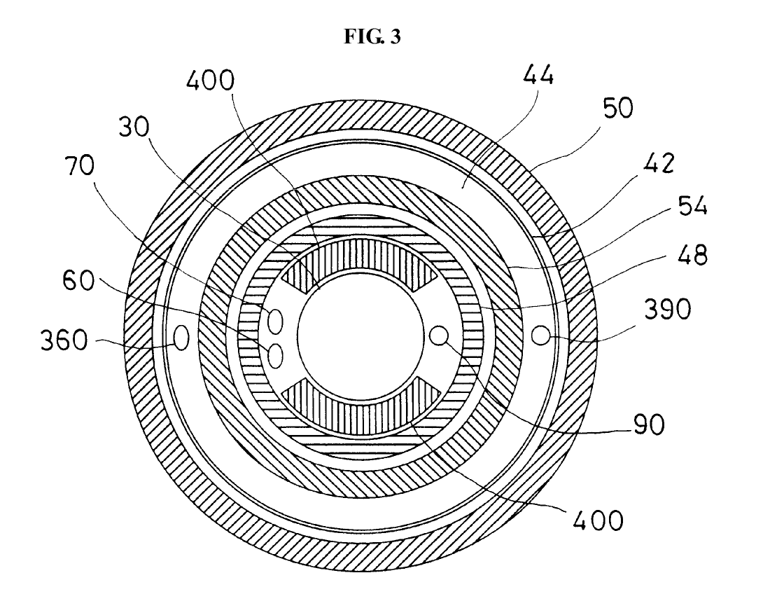

Next, the processing furnace 40 of the semiconductor manufacturing apparatus 10 for forming a SiC epitaxial film will be described with reference to FIGS. 2 and 3. In the processing furnace 40, a first gas supply nozzle 60 including a first gas supply port 68, a second gas supply nozzle 70 including a second gas supply port 72, and a first gas exhaust port 90 is shown as a representative example. In addition, a third gas supply port 360 configured to supply an inert gas and a second gas exhaust port 390 are shown.

The processing furnace 40 includes a reaction tube 42 that forms a reaction chamber 44. The reaction tube 42, which is formed of a heat-resistant material such as quartz or SiC, has a cylindrical shape with an upper end closed and a lower end opened. In a cylindrical hollow space of the reaction tube 42, the reaction chamber 44 is configured to concentrically receive the wafers 14 as substrates, which are formed of Si, SiC, or the like, using the boat 30 in a horizontal posture and stack and hold the wafers 14 vertically.

A manifold 36 is installed under the reaction tube 42 to form a concentric relationship with respect to the reaction tube 42. The manifold 36 is formed of, for example, stainless steel or some other material and has a cylindrical shape with upper and lower ends opened. The manifold 36 is installed to support the reaction tube 42. In addition, an O-ring (not shown) is installed as a seal member between the manifold 36 and the reaction tube 42. As the manifold 36 is supported by a holding body (not shown), the reaction tube 42 is installed in a vertical posture. The reaction vessel is formed by the reaction tube 42 and the manifold 36.

The processing furnace 40 includes an object to be heated 48 and an induction coil 50, which is a magnetic field generating part. The object to be heated 48 is disposed in the reaction chamber 44, and heated by a magnetic field generated by the induction coil 50 installed outside the reaction tube 42. As the object to be heated 48 generates heat, the inside of the reaction chamber 44 is heated.

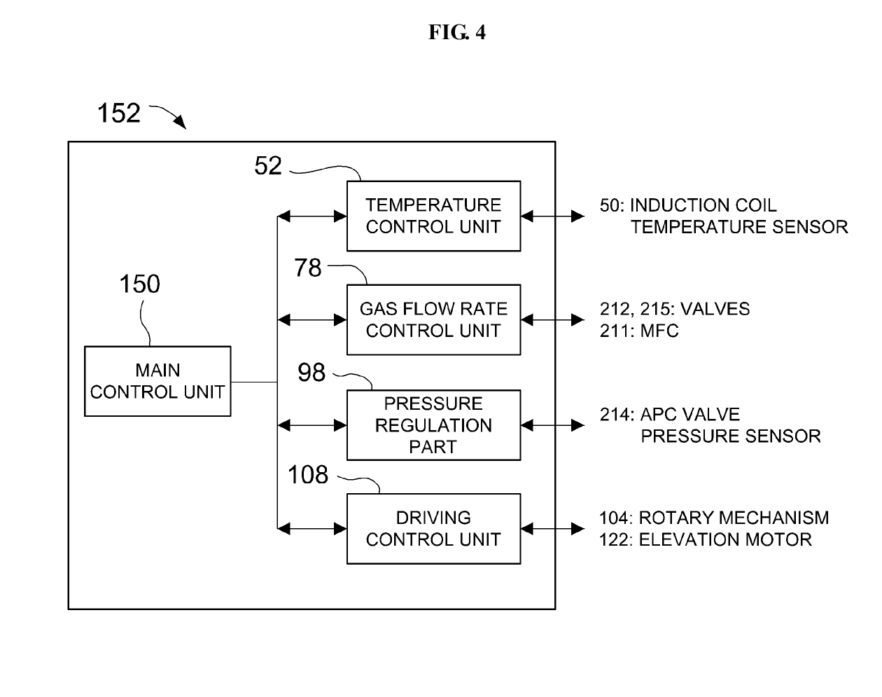

A temperature sensor (not shown), which is a temperature detecting body configured to detect a temperature in the reaction chamber 44, is installed in the vicinity of the object to be heated 48. The induction coil 50 and the temperature sensor are electrically connected to a temperature control unit 52 and configured such that the temperature in the reaction chamber 44 reaches a desired temperature distribution at a predetermined timing by adjusting a conduction state of the induction coil 50 based on temperature information detected by the temperature sensor (see FIG. 4).

In addition, preferably, structures 400 extending in a vertical direction and having an arc-shaped cross-section may be installed between the first and second gas supply nozzles 60 and 70 and the first gas exhaust port 90 in the reaction chamber 44, and between the object to be heated 48 and the wafer 14 in the reaction chamber 44, to fill a space between the object to be heated 48 and the wafer 14. For example, as shown in FIG. 3, as the structures 400 are installed to oppose each other, a gas supplied through the first and second gas supply nozzles 60 and 70 may be prevented from bypassing the wafer 14 along an inner wall of the object to be heated 48. When the structures 400 are formed of an insulating material or carbon felt, heat resistance can be increased and generation of particles can be suppressed.

An insulating material 54 formed of, for example, carbon felt, in which an electrical current cannot be easily induced, is installed between the reaction tube 42 and the object to be heated 48. As the insulating material 54 is installed, transfer of heat from the object to be heated 48 to the outside of the reaction tube 42 or to the reaction tube 42 can be suppressed.

In addition, in order to suppress transfer of heat in the reaction chamber 44 to the outside, an outer insulating wall such as a water cooling structure is installed outside the induction coil 50 to surround the reaction chamber 44. Further, a magnetic seal 58 is installed outside the outer insulating wall to prevent leakage of the magnetic field generated by the induction coil 50 to the outside.

As shown in FIG. 2, a first gas supply nozzle 60, in which at least one first gas supply port 68 is installed to supply at least a silicon atom-containing gas and a chlorine atom-containing gas to the wafer 14, is installed between the object to be heated 48 and the wafer 14. In addition, a second gas supply nozzle 70, in which at least a second gas supply port 72 is installed to supply at least a carbon atom-containing gas and a reducing gas to the wafer 14, is installed at a position different from the first gas supply nozzle 60 between the object to be heated 48 and the wafer 14. Further, similarly, the first gas exhaust port 90 is also disposed between the object to be heated 48 and the wafer 14. Furthermore, the third gas supply port 360 and the second gas exhaust port 390 are disposed between the reaction tube 42 and the insulating material 54.

In addition, the gas supplied to the first gas supply nozzle 60 and the second gas supply nozzle 70 is an example for explaining a structure of the apparatus, which will be described below in detail. Further, in the drawing, for the sake of simple description, one first gas supply nozzle 60 and one second gas supply nozzle 70 are disposed, which will also be described below in detail.

The first gas supply port 68 and the first gas supply nozzle 60 are formed of, for example, carbon graphite, and installed in the reaction chamber 44. In addition, the first gas supply nozzle 60 is installed at the manifold 36 to pass through the manifold 36. Here, when the SiC epitaxial film is formed, the first gas supply port 68 is configured to supply at least a silicon atom-containing gas such as monosilane (hereinafter, referred to as SiH₄) gas, and a chlorine atom-containing gas such as hydrogen chloride (hereinafter, referred to as HCl) gas into the reaction chamber 44 via the first gas supply nozzle 60.

The first gas supply nozzle 60 is connected to a first gas line 222. The first gas line 222 is connected to, for example, gas pipes 213a and 213b, and the gas pipes 213a and 213b are connected to, for example, a SiH₄ gas supply source 210a and a HCl gas supply source 210b via mass flow controllers 211a and 211b (hereinafter, referred to as MFCs), which are flow rate controllers (flow rate control means) of SiH₄ gas and HCl gas, and valves 212a and 212b.

According to the configuration, supply flow rates, concentrations, partial pressures, and supply timings of SiH₄ gas and HCl gas in the reaction chamber 44 may be controlled. The valves 212a and 212b, and the MFC 211a and 211b are electrically connected to a gas flow rate control unit 78, and configured to be controlled at a predetermined timing such that flow rates of the supplied gases reach predetermined flow rates (see FIG. 4). In addition, a first gas supply system, which is a gas supply system, may be constituted by the gas supply sources 210a and 210b of SiH₄ gas and HCl gas, the valves 212a and 212b, the MFCs 211a and 211b, the gas pipes 213a and 213b, the first gas line 222, the first gas supply nozzle 60 and at least one first gas supply port 68 installed at the first gas supply nozzle 60.

The second gas supply port 72 is formed of, for example, carbon graphite, and installed in the reaction chamber 44. In addition, the second gas supply nozzle 70 is installed at the manifold 36 to pass through the manifold 36. Here, when the SiC epitaxial film is formed, the second gas supply port 72 is configured to supply at least a carbon atom-containing gas such as propane (hereinafter, referred to as C₃H₈) gas, and a reducing gas such as hydrogen (H atom monomer or H2 molecule, hereinafter, referred to as H₂), into the reaction chamber 44 via the second gas supply nozzle 70. In addition, a plurality of second gas supply nozzles 70 may be installed.

The second gas supply nozzle 70 is connected to a second gas line 260. The second gas line 260 is connected to, for example, gas pipes 213c and 213d, and the gas pipes 213c and 213d are connected to a C₃H₈ gas supply source 210c via a MFC 211c and a valve 212c, which are flow rate control means of a carbon atom-containing gas such as C₃H₈ gas, and connected to a H₂ gas supply source 210d via a MFC 211d and a valve 212d, which are flow rate control means of a reducing gas such as H₂ gas.

According to the configuration, for example, supply flow rates, concentrations and partial pressures of C₃H₈ gas and H₂ gas may be controlled in the reaction chamber 44. The valves 212c and 212d and the MFCs 211c and 211d are electrically connected to the gas flow rate control unit 78, and configured to be controlled at a predetermined timing such that a supplied gas flow rate reaches a predetermined flow rate (see FIG. 4). In addition, a second gas supply system, which is a gas supply system, is constituted by the gas supply sources 210c and 210d of C₃H₈ gas and H₂ gas, the valves 212c and 212d, the MFCs 211c and 211d, the gas pipes 213c and 213d, the second gas line 260, the second gas supply nozzle 70, and the second gas supply port 72.

In addition, in the first gas supply nozzle 60 and the second gas supply nozzle 70, one or the number required by the number of wafers 14 of the first gas supply port 68 and the second gas supply port 72 may be installed in an arrangement region of a substrate.

### <Exhaust System>

As shown in FIG. 3, the first gas exhaust port 90 is disposed at an opposite position of the first gas supply nozzle 60 and the second gas supply nozzle 70. The gas exhaust pipe 230 connected to the first gas exhaust port 90 is installed at the manifold 36 to pass through the manifold 36. A vacuum exhaust apparatus 220 such as a vacuum pump is connected to a downstream side of the gas exhaust pipe 230 via a pressure sensor, which is a pressure detector (not shown), and an auto pressure controller (APC) valve 214 which is a pressure regulator. The pressure regulation part 98 is electrically connected to the pressure sensor and the APC valve 214, and the pressure regulation part 98 is configured such that a pressure in the processing furnace 40 is regulated to a predetermined pressure with a predetermined timing by adjusting an opening angle of the APC valve 214 based on the pressure detected by the pressure sensor (see FIG. 4).

As described above, at least a silicon atom-containing gas and a chlorine atom-containing gas are supplied through the first gas supply port 68 and at least a carbon atom-containing gas and a reducing gas are supplied through the second gas supply port 72. Since the supplied gas flows parallel to the wafers 14 formed of Si or SiC and is exhausted through the first gas exhaust port 90, all of the wafers 14 are efficiently and uniformly exposed to the gas.

In addition, as shown in FIG. 3, the third gas supply port 360 is disposed between the reaction tube 42 and the insulating material 54, and installed to pass through the manifold 36. Further, the second gas exhaust port 390 is disposed between the reaction tube 42 and the insulating material 54 to oppose the third gas supply port 360, and the second gas exhaust port 390 is connected to the gas exhaust pipe 230. The third gas supply port 360 is formed at a third gas line 240 passing through the manifold 36, and connected to a gas supply source 210e via a valve 212e and a MFC 211e. An inert gas such as a rare gas, for example, Ar gas, is supplied from the gas supply source 210e, and a gas contributing to SiC epitaxial film growth such as a silicon atom-containing gas or a carbon atom-containing gas or a chlorine atom-containing gas, or a mixture thereof, blocks penetration between the reaction tube 42 and the insulating material 54 to prevent unnecessary byproducts from sticking to an inner wall of the reaction tube 42 and an outer wall of the insulating material 54.

In addition, the inert gas supplied between the reaction tube 42 and the insulating material 54 is exhausted through the vacuum exhaust apparatus 220 via the APC valve 214 disposed at a downstream side of the gas exhaust pipe 230 rather than the second gas exhaust port 390.

### <Peripheral Configurations of Processing Furnace>

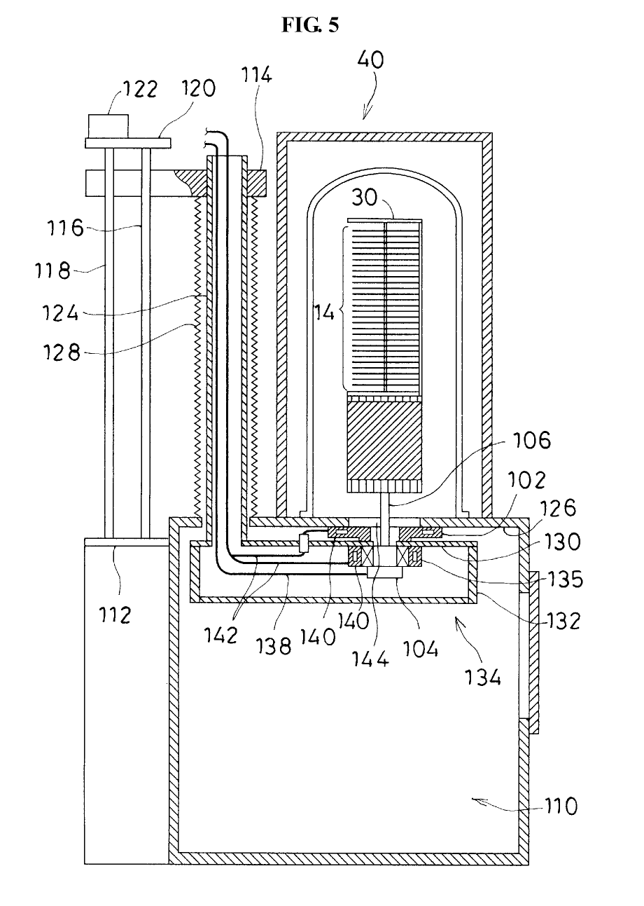

The processing furnace 40 and peripheral configurations thereof will now be described with reference to FIG. 5. A seal cap 102, which is a furnace port cover, is installed under the processing furnace 40 to hermetically block a lower-end opening of the processing furnace 40. The seal cap 102 is formed of, for example, a metal material such as stainless steel, and has a disc shape. An O-ring (not shown), which is a seal material in contact with a lower end of the processing furnace 40, is installed at an upper surface of the seal cap 102. A rotary mechanism 104 is installed at the seal cap 102, and a rotary shaft 106 of the rotary mechanism 104 is connected to the boat 30 through the seal cap 102 and configured to rotate the wafer 14 by rotating the boat 30.

In addition, the seal cap 102 is an elevation mechanism installed outside the processing furnace 40, and configured to be vertically elevated by an elevation motor 122 (described later) such that the boat 30 can be loaded/unloaded into/from the processing furnace 40. A driving control unit 108 is electrically connected to the rotary mechanism 104 and the elevation motor 122, and configured to control them to perform a predetermined operation with a predetermined timing (see FIG. 4).

A lower substrate 112 is installed at an outer surface of a load lock chamber 110, which is a preliminary chamber. A guide shaft 116 slidably engaged with an elevation platform 114, and a ball screw 118 threadedly engaged with the elevation platform 114, are installed at the lower substrate 112. In addition, an upper substrate 120 is installed at upper ends of the guide shaft 116 and the ball screw 118 vertically installed on the lower substrate 112. The ball screw 118 is rotated by the elevation motor 122 installed at the upper substrate 120. As the ball screw 118 is rotated, the elevation platform 114 is raised or lowered.

A hollow elevation shaft 124 is vertically installed at the elevation platform 114, a connecting portion of the elevation platform 114 and the elevation shaft 124 is hermetically sealed, and the elevation shaft 124 is configured to be raised or lowered with the elevation platform 114. The elevation shaft 124 passes through a top plate 126 of the load lock chamber 110, and a through-hole of the top plate 126 through which the elevation shaft 124 passes has a gap sufficient that the elevation shaft 124 does not contact the top plate 126.

In addition, a bellows 128, which is a hollow flexible body to cover surroundings of the elevation shaft 124, is installed between the load lock chamber 110 and the elevation platform 114, and the load lock chamber 110 is configured to be hermetically sealed by the bellows 128. Further, the bellows 128 has sufficient flexibility to correspond to an elevation length of the elevation platform 114, and an inner diameter of the bellows 128 is substantially larger than an outer diameter of the elevation shaft 124 and configured such that the bellows 128 does not contact the elevation shaft 124.

An elevation base plate 130 is horizontally fixed to a lower end of the elevation shaft 124, and a driving part cover 132 is hermetically installed at a lower surface of the elevation base plate 130 via a seal member such as an O-ring. A driving part receiving case 134 comprises the elevation base plate 130 and the driving part cover 132 so that the inside of the driving part receiving case 134 is isolated from an atmosphere in the load lock chamber 110.

In addition, the rotary mechanism 104 of the boat 30 is installed in the driving part receiving case 134, and surroundings of the rotary mechanism 104 are configured to be cooled by a cooling mechanism 135.

A power cable 138 is passed through a hollow part from an upper end of the elevation shaft 124 to be guided and connected to the rotary mechanism 104. Further, a cooling water flow path 140 is formed at the cooling mechanism 135 and the seal cap 102. Furthermore, a cooling water pipe 142 passes through the hollow part from the upper end of the elevation shaft 124 to be guided and connected to the cooling water flow path 140.

As the elevation motor 122 is driven to rotate the ball screw 118, the driving part receiving case 134 is raised and lowered via the elevation platform 114 and elevation shaft 124.

As the driving part receiving case 134 is raised, the seal cap 102 hermetically installed at the elevation base plate 130 blocks a furnace port 144, which is an opening of the processing furnace 40, so that the wafer can be processed. Then, as the driving part receiving case 134 is lowered, the boat 30 is lowered with the seal cap 102, and the wafer 14 can be unloaded to the outside.

### <Control Unit>

Control configurations of the respective parts of the semiconductor manufacturing apparatus 10 for forming a SiC epitaxial film will be described below with reference to FIG. 4.

The temperature control unit 52, the gas flow rate control unit 78, the pressure regulation part 98, and the driving control unit 108 make up an operation part and an input/output part, and are electrically to a main control unit 150 configured to control the entire semiconductor manufacturing apparatus 10. In addition, the temperature control unit 52, the gas flow rate control unit 78, the pressure regulation part 98, and the driving control unit 108 make up a controller 152.

### <Specification of Gases Supplied to Respective Gas Supply Systems>

Reasons for configuring the first gas supply system and the second gas supply system will now be described. The semiconductor manufacturing apparatus for forming the SiC epitaxial film needs to supply a source gas containing at least a silicon atom-containing gas and a carbon atom-containing gas into the reaction chamber 44 to form the SiC epitaxial film. In addition, when the plurality of wafers 14 are aligned and held in a horizontal posture and a multi-stage as in the embodiment, in order to improve uniformity between the wafers, the gas supply nozzles are installed in the reaction chamber 44 to supply the source gas through the gas supply ports around the wafers, respectively. Accordingly, an inside of the gas supply nozzle is also under the same conditions as the reaction chamber. Here, when a silicon atom-containing gas and a carbon atom-containing gas are supplied from the same gas supply nozzle, the source gases may be consumed by reacting with each other, such that their quantities are insufficient at a downstream side of the reaction chamber 44. And accumulations such as a SiC film accumulated through reaction in the gas supply nozzle block the gas supply nozzle to make supply of the source gases unstable, generating particles.

For these reasons, in the present embodiment, a silicon atom-containing gas is supplied via the first gas supply nozzle 60, and a carbon atom-containing gas is supplied via the second gas supply nozzle 70. As described above, since the silicon atom-containing gas and the carbon atom-containing gas are supplied through separate gas supply nozzles, the SiC film cannot accumulate in the gas supply nozzle. In addition, when concentrations and flow velocities of the silicon atom-containing gas and carbon atom-containing gas are to be adjusted, appropriate carrier gases may be supplied, respectively.

Further, in order to more efficiently use the silicon atom-containing gas, a reducing gas such as a hydrogen gas may be used. In this case, the reducing gas may be supplied via the second gas supply nozzle 70 that supplies the carbon atom-containing gas. When the reducing gas is supplied with the carbon atom-containing gas in this way, the reducing gas is mixed with the silicon atom-containing gas in the reaction chamber 44 such that the reducing gas becomes insufficient. Accordingly, decomposition of the silicon atom-containing gas may be suppressed in comparison with formation of the film, and accumulation of the Si film in the first gas supply nozzle can also be suppressed. In this case, the reducing gas can be used as a carrier gas of the carbon atom-containing gas. In addition, an inert gas such as argon (Ar) (in particular, a rare gas) may be used as the carrier gas of the silicon atom-containing gas to suppress accumulation of the Si film.

Further, a chlorine atom-containing gas such as HCl may be supplied through the first gas supply nozzle 60. As a result, even when the silicon atom-containing gas can be pyrolyzed and accumulate in the first gas supply nozzle, a chlorine etching mode can be performed to remove accumulated Si film in the first gas supply nozzle.

Furthermore, while an example configuration in which SiH₄ gas and HCl gas are supplied through the first gas supply nozzle 60, and C₃H₈ gas and H₂ gas are supplied through the second gas supply nozzle 70, has been described above with reference to FIG. 2, the present invention is not limited to that example.

In addition, while the example of FIG. 2 uses HCl gas as a chlorine atom-containing gas flowing when the SiC epitaxial film is formed, chlorine gas may also be used.

Further, instead of supplying the silicon atom-containing gas and the chlorine atom-containing gas when the SiC epitaxial film is formed, a single gas containing silicon atoms and chlorine atoms, for example, tetrachlorosilane (hereinafter, referred to as SiCl₄) gas, trichlorosilane (hereinafter, referred to as SiHCl₃) gas, and dichlorosilane (hereinafter, referred to as SiH₂Cl₂) gas, may be supplied. Of course, the gas containing silicon atoms and chlorine atoms may be a silicon atom-containing gas or a mixture of a silicon atom-containing gas and a chlorine atom-containing gas. In particular, since SiCl₄has a relatively high pyrolysis temperature, SiCl₄ is preferable to suppress consumption of Si in the nozzle.

In addition, while C₃H₈ gas is used as an example of a carbon atom-containing gas, ethylene (hereinafter, referred to as C₂H₄) gas and acetylene (hereinafter, referred to as C₂H₂) gas may also be used.

Further, while H₂ gas is used as an example of a reducing gas, the reducing gas is not limited thereto and a hydrogen atom-containing gas may also be used. Furthermore, at least one of rare gases Ar (argon) gas, He (helium) gas, Ne (neon) gas, Kr (krypton) gas, and Xe (xenon) gas, or a mixture of rare gases may be used as a carrier gas.

In the above, the silicon atom-containing gas is supplied via the first gas supply nozzle 60 and the carbon atom-containing gas is supplied via the second gas supply nozzle 70 to suppress accumulation of SiC film in the gas supply nozzle (hereinafter, a method of separately supplying the silicon atom-containing gas and carbon atom-containing gas is referred to as a separate method). However, while such a method can suppress accumulation of SiC film in the gas supply nozzle, the silicon atom-containing gas and carbon atom-containing gas need to be sufficiently mixed up until they reach the wafer 14 through the gas supply ports 68 and 72.

Accordingly, in consideration of wafer uniformity, the silicon atom-containing gas and carbon atom-containing gas may be premixed and supplied through the gas supply nozzle 60 (hereinafter, a method of supplying the silicon atom-containing gas and carbon atom-containing gas through the same gas supply nozzle is referred to as a premix method). However, when the silicon atom-containing gas and carbon atom-containing gas are supplied through the gas supply nozzle, the SiC film may be accumulated in the gas supply nozzle. Meanwhile, when a ratio (Cl/H) of an etching gas such as chlorine and a reducing gas such as hydrogen is increased, the silicon atom-containing gas can increase an etching effect by chlorine and suppress reaction of the silicon atom-containing gas. Accordingly, the silicon atom-containing gas, carbon atom-containing gas and chlorine-containing gas are supplied through one of the gas supply nozzles, and the reducing gas such as hydrogen gas used in a reduction reaction is supplied through the other gas supply nozzle so that a Cl/H ratio in the gas supply nozzle can be increased and accumulation of SiC film can be suppressed.

### <Configuration of Gas Supply Nozzle>

Here, as described above, accumulation in the gas supply nozzle can be suppressed by varying a method of supplying a source gas such as silicon atom-containing gas contributing to formation of the SiC film. However, separately supplied source gases are mixed just after injection through the gas supply ports 68 and 72. When the source gases are mixed around the gas supply ports 68 and 72, the SiC film may accumulate on the gas supply port, and particles may be generated due to blocking of the gas supply port or peeling-off of the accumulated SiC film.

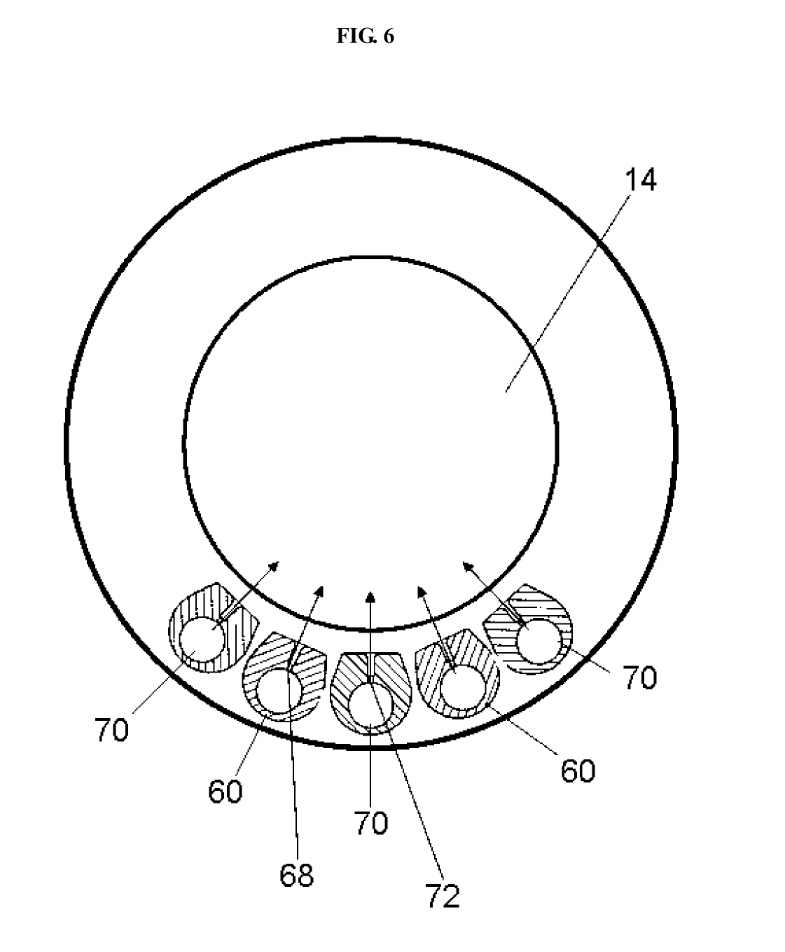

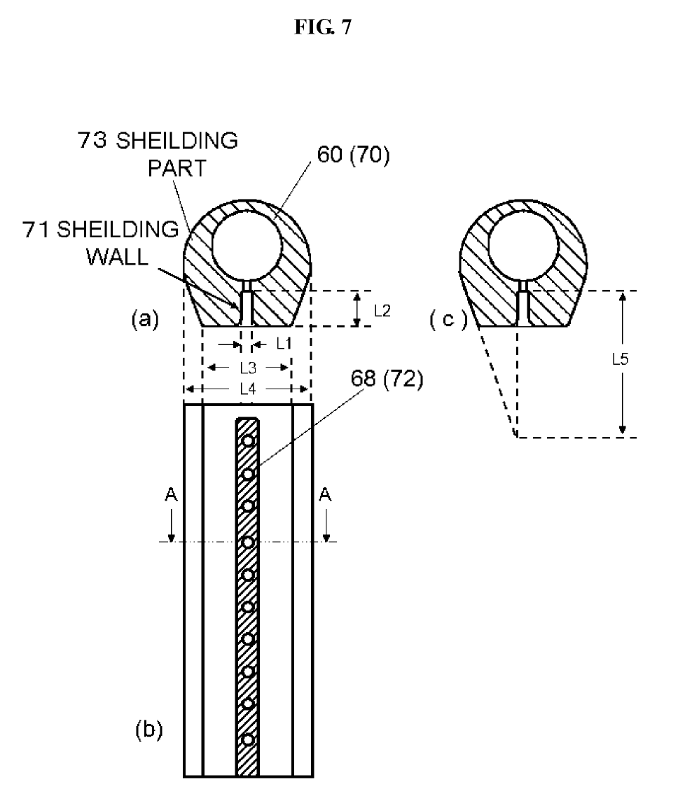

A structure for suppressing accumulation of SiC film around the gas supply port will be described with reference to FIGS. 6 and 7. In addition, the gas supply method will be described as the separate method. First, disposition of the gas supply nozzles will be described with reference to FIG. 6. FIG. 6 is a cross-sectional view of the reaction chamber 44 seen from above, showing necessary members only for ease of understanding. As shown in FIG. 6, the first gas supply nozzles 60 configured to supply a silicon atom-containing gas and the second gas supply nozzles 70 configured to supply a carbon atom-containing gas are alternately disposed. According to the alternate disposition, mixing of the silicon atom-containing gas and carbon atom-containing gas may be accelerated. In addition, the number of the first gas supply nozzles and second gas supply nozzles may be an odd number. When the number is an odd number, the source gas can be supplied symmetrically with respect to a center of the second gas supply nozzles 70, and uniformity of the wafer 14 can be increased.

Further, in FIG. 6, the second gas supply nozzles 70 configured to supply a carbon atom-containing gas are disposed at a center and both sides, and the first gas supply nozzles 60 configured to supply a silicon atom-containing gas are disposed between the second gas supply nozzles. Of course, the first gas supply nozzles 60 configured to supply a silicon atom-containing gas may be disposed at a center and both sides, and the second gas supply nozzles 70 configured to supply a carbon atom-containing gas may be disposed between the first gas supply nozzles. Furthermore, preferably, the second gas supply nozzles 70 configured to supply a carbon atom-containing gas may be disposed at a center and both sides, and the first gas supply nozzles 60 configured to supply a silicon atom-containing gas may be disposed between the second gas supply nozzles. According to such a disposition, as a flow rate ratio (center/both ends) of H₂, the carrier gas supplied in large quantity (becomes a main stream of a field) together with the carbon atom-containing gas, is adjusted, gas flow on the wafer can be controlled and film thickness can be easily controlled. In addition, when the premix method is used, the silicon atom-containing gas, the carbon atom-containing gas and the chlorine-containing gas may be supplied through the first gas supply nozzles 60, and hydrogen gas, which is a reducing gas, may be supplied through the second gas supply nozzles 70. As a result, by adjusting the flow rate ratio (center/both ends) of H₂, the carrier gas supplied in large quantity (becomes a main stream of a field), gas flow on the wafer can be controlled and film thickness can be easily controlled.

Next, each of the gas supply nozzles will be described with reference to FIG. 7. FIG. 7 shows a relationship between a front view of one of the gas supply nozzles and a cross-sectional view taken along line A-A. FIG. 7A is a cross-sectional view taken along line A-A, and FIG. 7B is a front view. Each of the gas supply nozzles 60 or 70 includes a shielding part 73 configured to stop gas injected through another gas supply port from being sprayed at the gas supply port 68 or 72, i.e., a shielding wall 71 extending in a direction of the wafer to shield the gas supply port 68 or 72. A gap L1 between inner walls of the shielding wall 71 is larger than a diameter of the gas supply port 68 or 72. Accordingly, in comparison with the gas supply port, blockage cannot easily occur. In addition, a length L2 from the gas supply port to a front end of the shielding wall 71 is larger than the gap L1 between the inner walls of the shielding wall 71, so that backward deflection of gas can be prevented.

Further, a width L3 of a front end part included in the shielding wall 71 of the gas supply nozzle is smaller than a width L4 of the gas supply nozzle when the gas supply port is seen from a front view. As shown in FIG. 6, the gas supply nozzles may be arranged equidistant from the wafer in a circumferential direction, rather than in a straight arrangement. Here, when the width L3 of the front end part is smaller than the width L4 of the gas supply nozzle, since an outer wall of the gas supply nozzle narrows toward the wafer center, the gas supply nozzles can be densely disposed. By densely disposing the gas supply nozzles, an amount of a source gas flowing between the gas supply nozzles can be reduced, and an amount of gas reaching the wafer can be increased.

In addition, as shown in FIG. 7C, the front end part of the shielding wall 71 has a structure configured by cutting a triangle region generated when an outer wall of the shielding wall formed in an inclined direction with respect to the ground and the inner wall of the shielding wall formed in a longitudinal direction cross each other. In other words, the length L2 of the inner wall of the shielding wall 71 is smaller than a length L5 of an extension line of the inner wall of the shielding wall until the extension line crosses an extension line of the outer wall of the shielding wall 71. According to the structure, contact of the gas supplied through the gas supply port 68 or 72 with the inner wall of the shielding wall 71 and slowdown of the velocity of the gas stream can be suppressed.

In addition, corners of the front end part after the cutting are chamfered and rounded. When the corners of the front end part are not chamfered, the corners may act as starting points for the accumulation of SiC film in a beak shape. However, as described in the embodiment, as the corners are chamfered and rounded, the SiC film still accumulates but in a planar shape, and thus generation of particles can be suppressed.

Further, in FIG. 7, while the shielding wall 71 and a main body of the gas supply nozzle are integrally formed with each other, an individual shielding wall 71 may be separately installed at a conventional circular (or oval) gas supply nozzle.

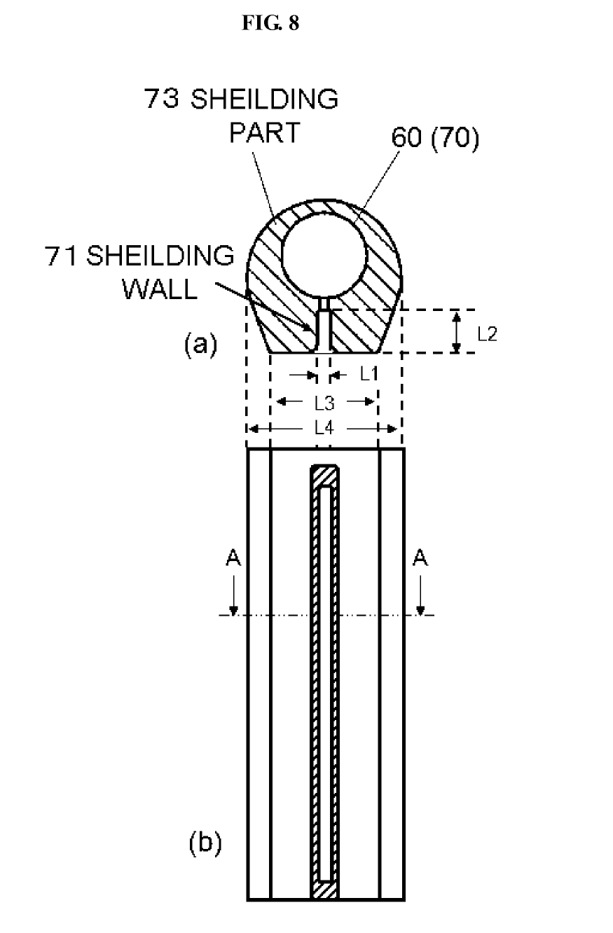

Furthermore, the gas supply ports 68 and 72 may have a slit shape as shown in FIG. 8, rather than a plurality of holes shown in FIG. 7. While the slit shape may reduce a velocity of the gas stream and a growth velocity of the epitaxial film may be reduced, mixing of the source gases supplied through the two different gas supply nozzles can be accelerated and uniformity on the wafer can be improved. In addition, in this case, a gap L1 between the inner walls of the shielding wall 71 may be larger than a width of the slit-shaped gas supply port. That is, reviewing FIGS. 7 and 8, the gap L1 between the inner walls of the shielding wall 71 may be larger than the width of the gas supply port parallel to a plane of the wafer.

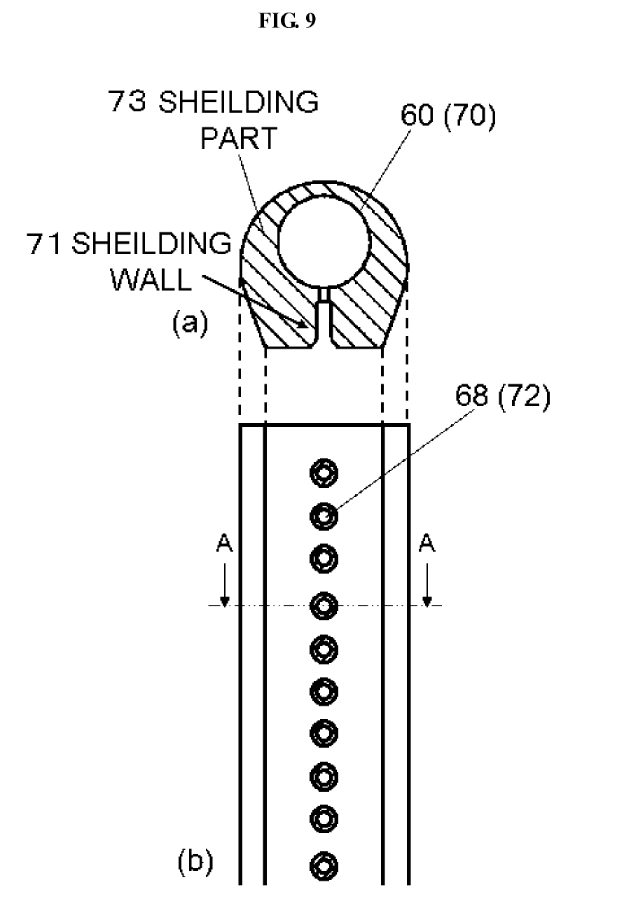

In addition, the shielding wall 71 may be configured to surround the gas supply port 68 or 72 as shown in FIG. 9, rather than interposing the gas supply port therebetween. Accordingly, while the source gas injected through the gas supply port may contact the inner walls of the shielding wall 71, slowing its velocity, since the inner wall surrounds the gas supply port, backward deflection of the gas can be better prevented than in the structure shown in FIG. 7.

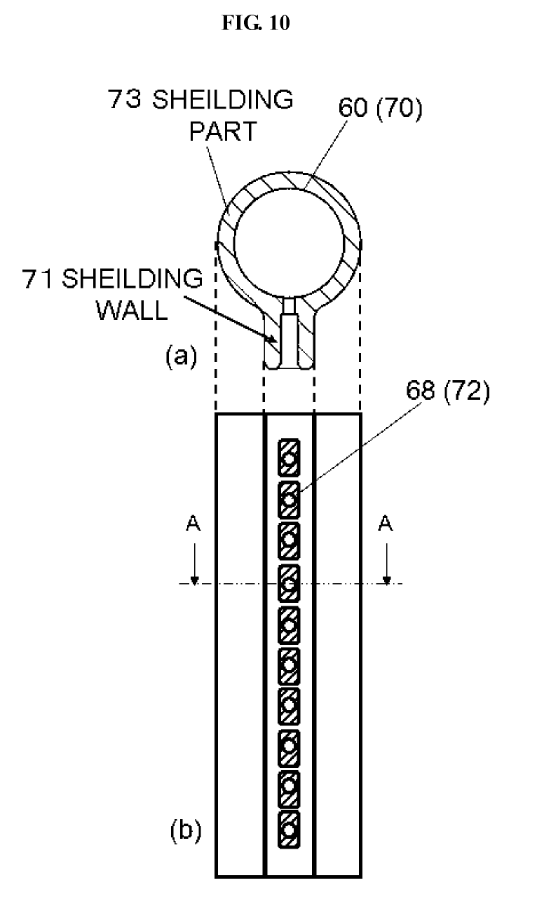

Further, outer walls of the shielding wall 71 may be configured to extend parallel to the inner walls of the shielding wall 71 as shown in FIG. 10. According to this configuration, while a gap between the gas supply nozzles may be increased, the weight of the gas supply nozzle may be reduced. In addition, while the shielding wall 71 of FIG. 10 is configured to surround the gas supply port, the shielding wall 71 may be configured to interpose the gas supply port as shown in FIG. 7. Further, the gas supply part may be formed in a slit shape, rather than the plurality of holes.

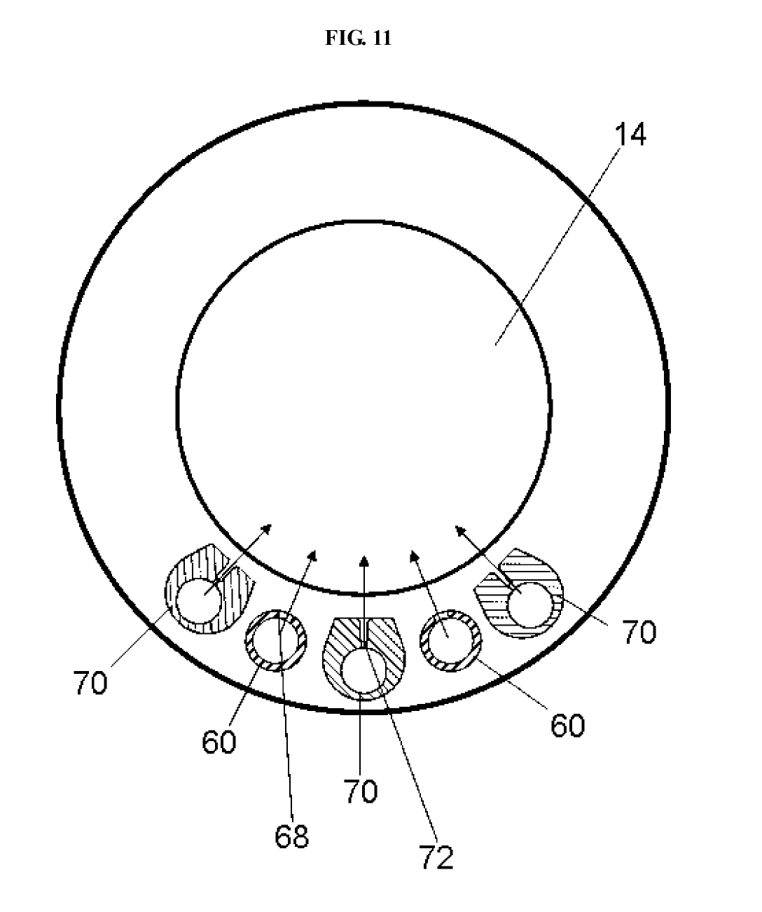

Next, a variant of FIG. 6 will be described. While FIG. 6 shows the shielding walls installed at both sides of the first gas supply nozzle 60 and the second gas supply nozzle 70, there is no need to install the shielding walls at all of the gas supply nozzles; rather they may be installed at only some of the gas supply nozzles. In particular, when a chlorine atom-containing gas is supplied through the first gas supply nozzle 70, since chlorine atoms have an effect of suppressing formation of the film, formation of the film on the gas supply port can be suppressed even though there is no shielding wall. Accordingly, as shown in FIG. 11, the first gas supply nozzle 60 may be a cylindrical gas supply nozzle with no shielding wall, and the second gas supply nozzle 70 may be a gas supply nozzle with a shielding wall.

In particular, in the case of the premix method, the shielding wall may not be installed at the second gas supply port 72. Since the reducing gas is injected through the second gas supply port 72, a gas, which becomes a source for forming a film, is not supplied. Accordingly, even when the gas injected through the first gas supply port 68 is directed to the second gas supply port, concentration of the gas may be lowered. Meanwhile, a flow velocity of the reducing gas is larger than that of the silicon atom-containing gas or carbon atom-containing gas. Accordingly, even when the shielding wall is not installed, a required gas flow velocity may be substantially obtained.

### <Method of Forming SiC Film>

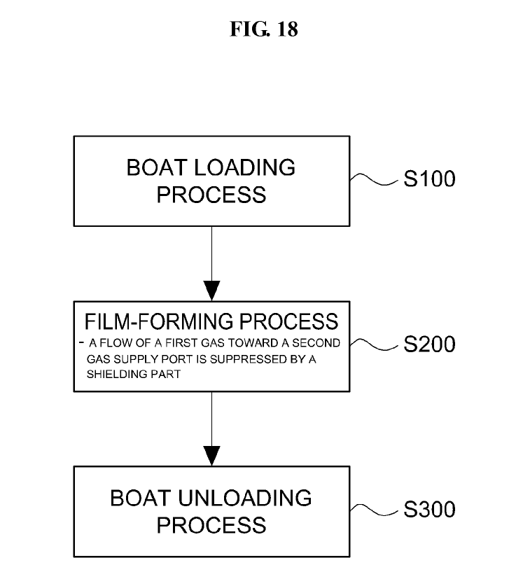

A method of manufacturing a substrate including a SiC film formed on a substrate such as a wafer 14 formed of SiC, which is a process employed in the manufacture of semiconductor devices, using the semiconductor manufacturing apparatus 10 will be described with reference to FIG. 18. In addition, in the following description, operations of the respective parts of the semiconductor manufacturing apparatus 10 are controlled by the controller 152.

First, when the pod 16, in which the plurality of wafers 14 are received, is set to the pod stage 18, the pod 16 is conveyed by the pod conveyance apparatus 20 from the pod stage 18 to the pod receiving shelf 22 and stored thereon. Next, the pod 16 stored on the pod receiving shelf 22 is conveyed to the pod opener 24 to be set by the pod conveyance apparatus 20, the cover of the pod 16 is opened by the pod opener 24, and the number of wafers 14 received in the pod 16 is detected by the substrate number detector 26.

Next, the wafer 14 is extracted from the pod 16 disposed at a position of the pod opener 24 and transferred to the boat 30 by the substrate transfer apparatus 28.

When the plurality of wafers 14 are charged into the boat 30, the boat 30 holding the wafers 14 is loaded into the reaction chamber 44 by an elevation operation of the elevation platform 114 and the elevation shaft 124 by the elevation motor 122 (boat loading) (S100). In this state, the seal cap 102 seals the lower end of the manifold 36 via the O-ring (not shown).

After loading the boat 30, the inside of the reaction chamber 44 is evacuated by the vacuum exhaust apparatus 220 to a predetermined pressure (vacuum level). At this time, a pressure in the reaction chamber 44 is measured by a pressure sensor (not shown), and the APC valve 214 in communication with the first gas exhaust port 90 and the second gas exhaust port 390 is feedback-controlled based on the measured pressure. In addition, the object to be heated 48 is heated such that the wafer 14 and the inside of the reaction chamber 44 reach a predetermined temperature. Here, a conduction state of the induction coil 50 is feedback-controlled based on temperature information detected by a temperature sensor (not shown) such that the inside of the reaction chamber 44 reaches a predetermined temperature distribution. Then, the boat 30 is rotated by the rotary mechanism 104, and the wafer 14 is rotated in a circumferential direction thereof.

Next, the silicon atom-containing gas and chlorine atom-containing gas contributing to the SiC epitaxial growth reaction are supplied from the gas supply sources 210a and 210b, respectively, to be injected into the reaction chamber 44 through the first gas supply port 68. In addition, after adjusting an opening angle of the MFCs 211c and 211d corresponding to the carbon atom-containing gas and the H₂ gas, which is a reducing gas, to a predetermined flow rate, the valves 212c and 212d are opened, and the gases flow through the second gas line 260 and pass through the second gas supply nozzle 70 to be introduced into the reaction chamber 44 via the second gas supply port 72.

The gas supplied through the first gas supply port 68 and the second gas supply port 72 passes through the inside of the object to be heated 48 in the reaction chamber 44, and is exhausted through the gas exhaust pipe 230 via the first gas exhaust port 90. The gas supplied through the first gas supply port 68 and the second gas supply port 72 contacts the wafer 14 formed of SiC or some other material when the gas passes through the reaction chamber 44, to perform the SiC epitaxial film growth on a surface of the wafer 14. At this time, a flow toward another gas supply port is suppressed by the shielding wall installed at the gas supply nozzle, thereby improving wafer uniformity.

In addition, after adjusting an opening angle of the MFC 211e corresponding to the Ar gas, which is a rare inert gas, from the gas supply source 210e to a predetermined flow rate, the valve 212e is opened, and the gas flows through the third gas line 240 and is supplied into the reaction chamber 44 through the third gas supply port 360. The Ar gas, which is a rare inert gas, supplied through the third gas supply port 360 passes between the insulating material 54 and the reaction tube 42 in the reaction chamber 44 and is exhausted through the second gas exhaust port 390 (S200).

Next, when a predetermined time elapses, supply of the gas is stopped, an inert gas is supplied from an inert gas supply source (not shown), a space inside the object to be heated 48 in the reaction chamber 44 is filled with the inert gas, and a pressure in the reaction chamber 44 is returned to normal.

After that, the seal cap 102 is lowered by the elevation motor 122 to open the lower end of the manifold 36, the processed wafer 14 held on the boat 30 is unloaded to the outside of the reaction tube 42 from the lower end of the manifold 36 (boat unloading) (S300), and the boat 30 goes on standby at a predetermined position until the wafer 14 held on the boat 30 is cooled. When the wafer 14 on the boat 30 on standby is cooled to a predetermined temperature, the wafer 14 is extracted from the boat 30 by the substrate transfer apparatus 28 and conveyed and received into the empty pod 16 set by the pod opener 24. After that, the pod 16 receiving the wafer 14 is conveyed to the pod receiving shelf 22 or the pod stage 18 by the pod conveyance apparatus 20. As a result, a series of operations of the semiconductor manufacturing apparatus 10 are completed.

As described above, since at least the silicon atom-containing gas and chlorine atom-containing gas are supplied through the first gas supply port 68, and at least the carbon atom-containing gas and reducing gas are supplied through the second gas supply port 72, film accumulation in the first gas supply nozzle 60 and the second gas supply nozzle 70 is suppressed. In addition, as the silicon atom-containing gas, the chlorine atom-containing gas, the carbon atom-containing gas, and H₂ reducing gas supplied through the first gas supply nozzle 60 and the second gas supply nozzle 70 react with each other in the reaction chamber 44, when the plurality of wafers 14 formed of SiC or some other material are horizontally held in a multi-stage, uniform SiC epitaxial film growth can be performed.

As described above, the second gas injected through at least the second gas supply port 72 is stopped from flowing toward the first gas supply port 68 by the shielding wall, which is the shielding part, thereby suppressing accumulation of film in the gas supply port and enabling the manufacture of wafers 14 having uniform quality.

### Second Embodiment

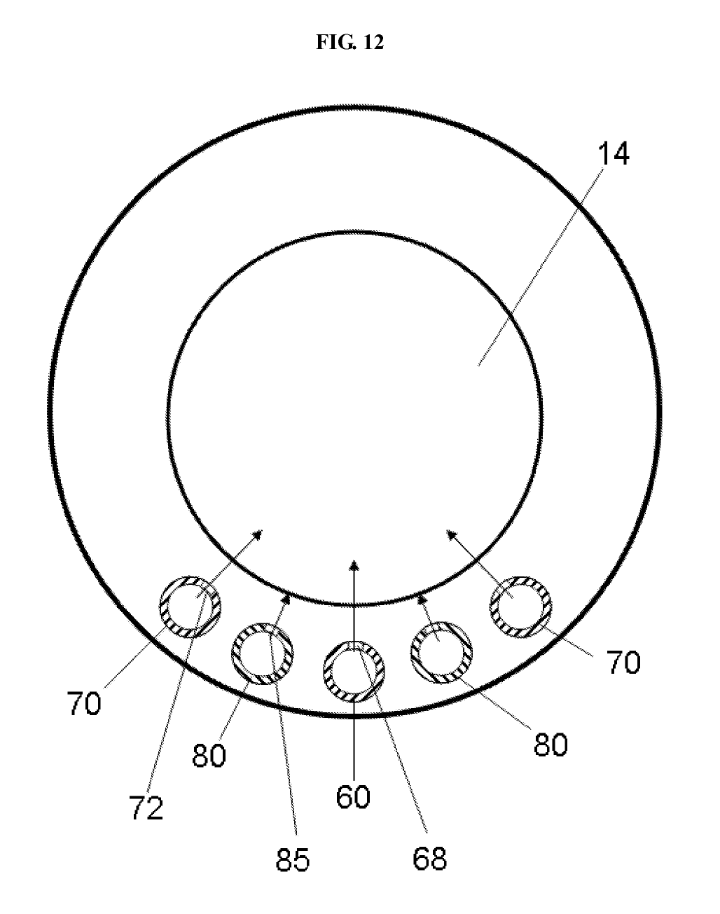

Next, a second embodiment in which blocking of the gas supply ports 68 and 72 is suppressed will be described below with reference to FIG. 12. The following description will focus on features of the second embodiment which distinguish from those of the first embodiment.

In the second embodiment, as shown in FIG. 12, a fourth gas supply nozzle 80 is disposed between the first gas supply nozzle 60 disposed at a center and the second gas supply nozzles 70 disposed at both ends. The fourth gas supply nozzle 80 supplies an inert gas such as argon (Ar) gas through the fourth gas supply port 85. That is, a flow of the inert gas supplied through the fourth gas supply port 85 is provided between a flow of the source gas supplied through the first gas supply port 68 and a flow of the source gas supplied through the second gas supply nozzle 72. As a result, flow of the source gas from the first gas supply nozzle 60 to the second gas supply nozzle 70 can be blocked by the flow of the inert gas supplied through the fourth gas supply port 85 around the gas supply port, and deflection of the source gas back into the second gas supply nozzle 70 can be prevented.

In this case, when the flow of the inert gas is too strong, since mixing of the source gas supplied through the first gas supply nozzle 60 and the source gas supplied through the second gas supply nozzle 70 is also suppressed, a flow rate of the inert gas supplied through the fourth gas supply nozzle 80 may be smaller than that of the source gas supplied through the first and second gas supply nozzles 60 and 70. In addition, a configuration shown in FIG. 12 may be applied to both of the separate method and the premix method.

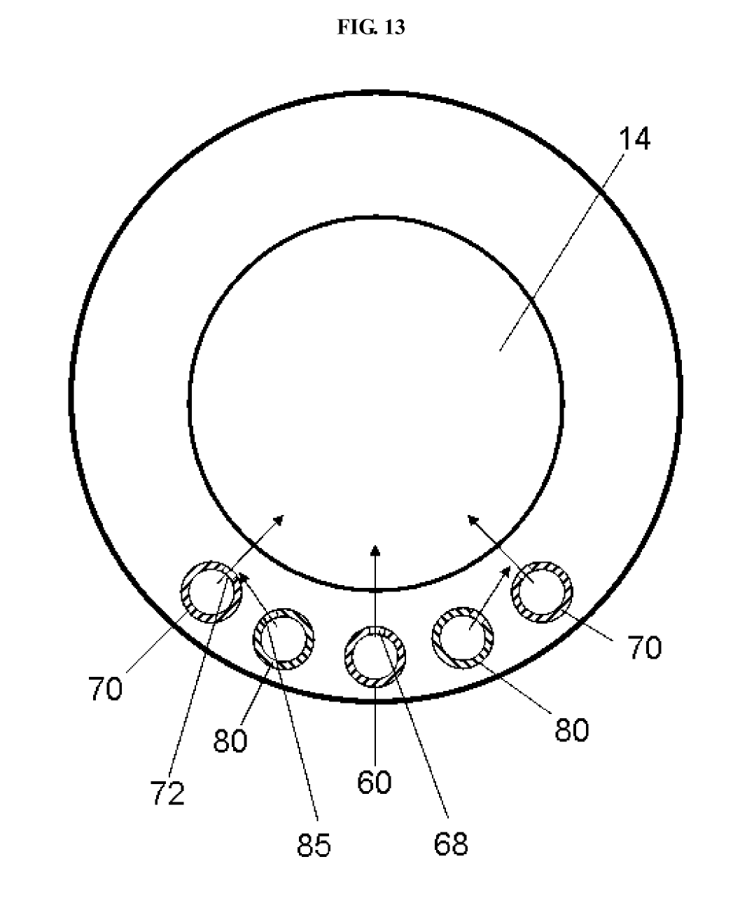

A variant will now be described with reference to FIG. 13. The variant is distinguished from the structure of FIG. 12 in that a fourth gas supply port 85 is installed and pointed at a second gas supply port 72. As described above, as the fourth gas supply port 85 is installed toward the second gas supply port 72 and the inert gas is directly injected toward the second gas supply port 72, flow of the source gas from the first gas supply port 68 to the second gas supply port 72 can be more efficiently blocked.

In addition, the structure shown in FIG. 13 employs the separate method, which is a gas supply method, and the silicon atom-containing gas and chlorine atom-containing gas are supplied through the first gas supply nozzle 60. As described above, the chlorine atoms have an effect of suppressing formation of the film. Accordingly, a gas stream of the inert gas may be injected to a side of the structure at which the chlorine atom is not supplied (in this case, the second gas supply nozzle 70), rather than a side of the structure at which the chlorine atom-containing gas is supplied.

In the case of the premix method, the silicon atom-containing gas and carbon atom-containing gas, which are source materials of the SiC film, are supplied through the first gas supply port 68, and a reducing gas is supplied through the second gas supply port 72. Accordingly, since the source gases, which accumulate as the SiC film, are supplied through the first gas supply port 68, a portion having a highest concentration is a region adjacent to the first gas supply port 68. As a result, the inert gas is supplied toward the first gas supply port 68 to suppress introduction of the reducing gas and thereby suppress accumulation of SiC film.

In addition, while FIG. 13 shows the inert gas supplied through the fourth gas supply port 85 being directly injected at the second gas supply port 72, the direction of the fourth gas supply port 85 is not limited thereto but may be directed toward a side adjacent to the second gas supply port 72 (in the case of the premix method, the first gas supply port 68) with respect to a center of the wafer 14.

### Third Embodiment

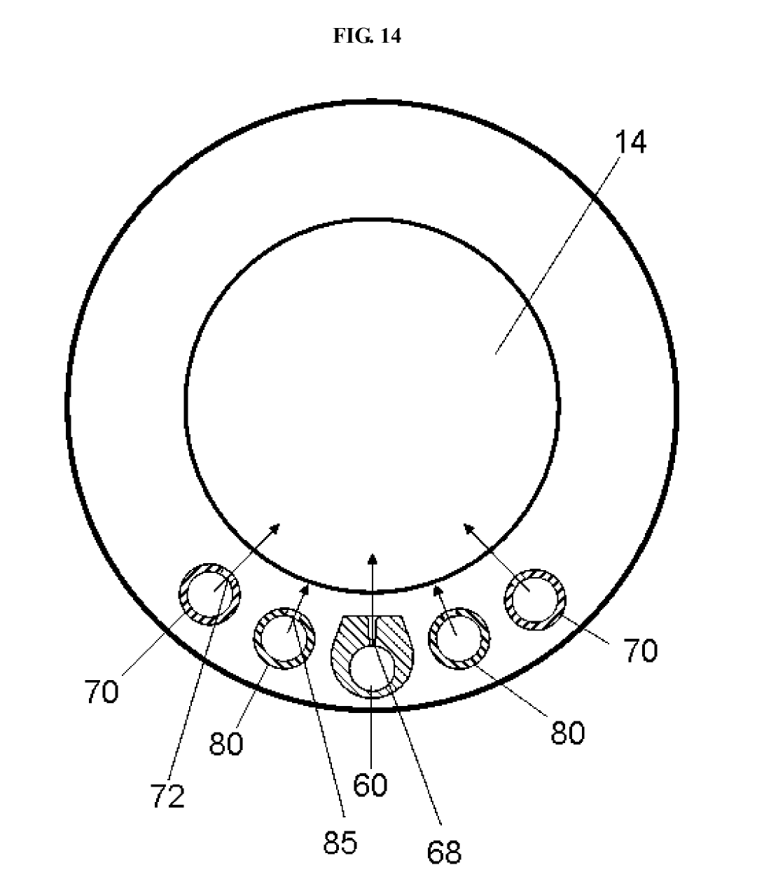

Next, a third embodiment will now be described with reference to FIG. 14. The following description will focus on features of the third embodiment which distinguish from those of the first and second embodiments. In the third embodiment, a case using a premix method is presented. As shown in FIG. 14, a first gas supply nozzle 60 includes a shielding wall, and a fourth gas supply nozzle 80 configured to supply an inert gas is installed between the first gas supply nozzle 60 and a second gas supply nozzle 70. In the case of the premix method, as described above, the SiC film may accumulate on the first gas supply port 68. For this reason, in this embodiment, backward deflection of a reducing gas from the second gas supply port to the first gas supply port 68 is suppressed by an inert gas, and also suppressed by the shielding wall installed at the first gas supply nozzle. As a result, accumulation of SiC film in the gas supply port can be suppressed.

In addition, in the case of the separate method, when the shielding walls are installed at both of the first gas supply nozzle 60 and second gas supply nozzle 70, the accumulation may be more efficiently suppressed.

While embodiments have been described, various modifications may be made without departing from the spirit of the present invention. For example, since the present invention was conceived as the result of a review of the batch type vertical SiC epitaxial growth apparatus, the embodiments concerning SiC epitaxial growth have been described. However, even in forming another film, when gases used to form a film are supplied through two gas supply nozzles and the gas supply port is under the same conditions as the reaction chamber, an accumulated film may adhere to the gas supply port. In this case, according to the configuration of the present invention, of course, such film adhesion to the gas supply port can be suppressed.

### Fourth Embodiment

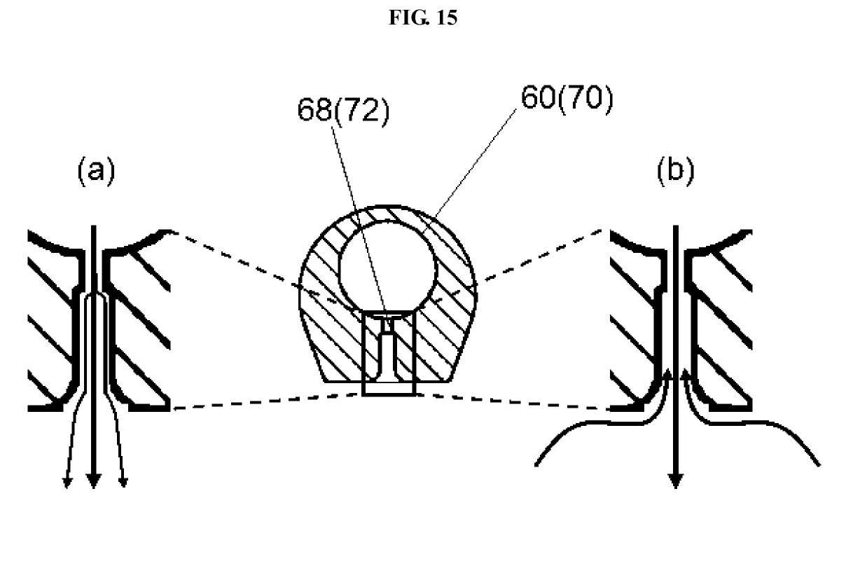

Next, a fourth embodiment will now be described with reference to FIGS. 15 to 17. The following description will focus on features of the fourth embodiment which distinguish from those of the first to third embodiments. In the first embodiment, the configuration of the gas supply nozzle including the shielding wall was described. However, when a flow velocity of the source gas supplied through the gas supply nozzle is increased, the following problems occur. That is, when the flow velocity is decreased as shown in FIG. 15A, the source gas injected through the gas supply port 68 or 72 exits through the gas supply port 68 or 72 and then passes through a shielding wall region while diffusing. Accordingly, since the source gas injected through the gas supply port 68 or 72 is injected along the sidewall of the shielding wall, the source gas injected through the other gas supply port does not intrude into the shielding wall region. However, as the flow velocity of the source gas injected through the gas supply port 68 or 72 is increased, a penetration force of the source gas is increased and the source gas exits the shielding wall region without diffusion. Then, as shown in FIG. 15B, a gap is generated between a gas stream of the source gas and the shielding wall, and thus, the source gas injected through the other gas supply port 68 or 72 may penetrate the gap to form an accumulated film in the shielding wall. As a result, the source gas injected through the gas supply port 68 or 72 contacts the accumulated film, causing reduction in velocity and generation of particles. In particular, in the SiC epitaxial growth apparatus, it is particularly challenging to enable the hydrogen gas to flow as a main stream around the second gas supply nozzle 70 through which the hydrogen gas flows.

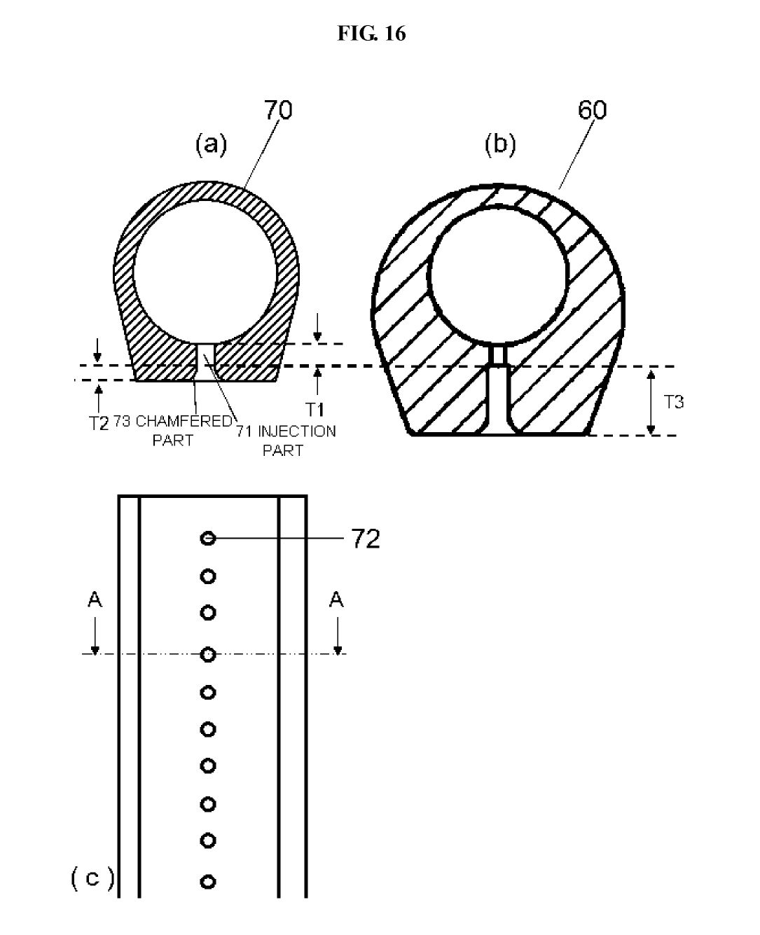

For this reason, in this embodiment, as shown in FIG. 16A, the shielding wall is not installed at the gas supply nozzle 70, and the gas supply port 72 is chamfered. As the chamfered structure is provided, an injection part 71 of the source gas is wider than the gas supply port 72, and thus, nozzle blocking can be suppressed. In addition, the chamfering is performed by increasing a thickness of the gas supply port of the gas supply nozzle having a cylindrical shape by an extent of the chamfering, rather than being provided by cutting the gas supply port 72. Accordingly, the gas supply port 72 of the embodiment shown in FIG. 16A is configured to include a straight injection part 71 having a length T1, and a chamfered part 73, which gradually widens in a gas injection direction. As described above, as a thickness of the gas supply port is increased by the extent of the chamfering, the length T1 of the plurality of gas supply ports 72 installed at the one gas supply nozzle 70 can be made substantially uniform, regardless of chamfering precision. Accordingly, the flow velocity of the source gas injected through the gas supply ports 72 can be kept uniform.

In addition, a length T2 of the chamfered part 73 of the gas supply nozzle of the fourth embodiment in the gas injection direction is smaller than a length T3 of the shielding wall of the gas supply nozzle of the first embodiment in the gas injection direction. Accordingly, a gap between the shielding wall and the rapid gas stream disappears, and contact between the gas stream and the accumulation is suppressed.

Further, as shown in FIG. 16C, the configuration of the gas supply nozzle in the embodiment may have chamfered parts 73 formed to surround the gas supply ports 72. For example, when the gas support parts are interposed as shown in FIG. 7, the gaps between the gas supply ports are generated, and thus, the source gas injected through the other gas supply nozzles may penetrate the gaps.

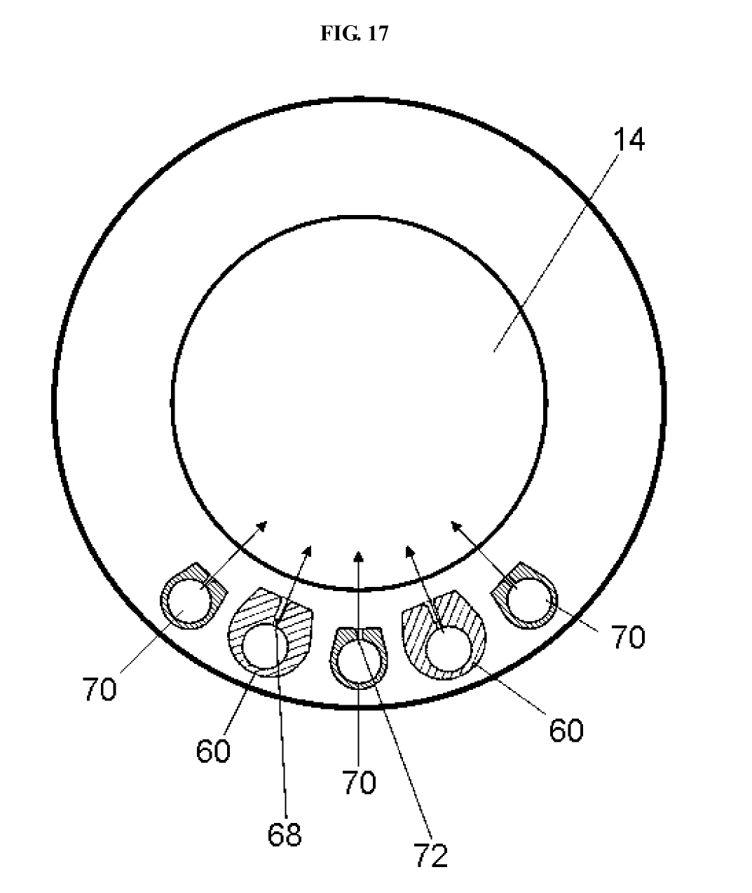

In addition, as shown in FIG. 17, the first gas supply nozzle 60 may employ the gas supply nozzle to which the shielding wall of the first embodiment is attached, and the second gas supply nozzle 70 may employ the chamfered gas supply nozzle described in the fourth embodiment. The reasons for employing the chamfered gas supply nozzle described in the fourth embodiment as the second gas supply nozzle 70 are as described above. In addition, the reason for employing the gas supply nozzle to which the shielding wall of the first embodiment is attached as the first gas supply nozzle 60 is that the shielding wall has an appropriate length for reducing velocity somewhat and easily facilitating diffusion. Accordingly, the silicon atom-containing gas supplied through the first gas supply nozzle 60 can be easily diffused toward and mixed with the carbon atom-containing gas supplied through the second gas supply nozzle 70.

While the present invention has been described with reference to embodiments, various modifications may be made without departing from the spirit of the present invention. For example, since the present invention was conceived as a result of a review of the SiC epitaxial growth apparatus, the embodiments of the SiC epitaxial growth apparatus have been described. However, the present invention is not limited thereto but may be applied to any substrate processing apparatus in which two kinds of gases are mixed in the reaction chamber.

The following is some additional description concerning embodiments of the present invention.
(1) According to an aspect of the present invention, there is provided a substrate processing apparatus including: a reaction chamber configured to accommodate a plurality of substrates; a heating part installed to cover the reaction chamber and configured to heat the reaction chamber; and a first gas supply pipe installed to extend in the reaction chamber, wherein the first gas supply pipe includes: a first gas supply port configured to inject a first gas toward the plurality of substrates; and first shielding walls installed at both sides of the first gas supply port to expose the first gas supply port and configured to extend toward the plurality of substrates from the first gas supply port.
(2) In the substrate processing apparatus according to (1), the apparatus further includes a second gas supply pipe including a second gas supply port configured to inject a second gas toward the plurality of substrates, the second gas supply pipe extending in the reaction chamber.
(3) In the substrate processing apparatus according to (2), wherein a width of an outer wall of each of the first shielding walls is smaller than that of the first gas supply pipe when the first gas supply port is seen from front.
(4) In the substrate processing apparatus according to (2) or (3), a distance from a front end part of the first shielding walls to the first gas supply port is greater than a gap between inner walls of the first shielding walls.
(5) In the substrate processing apparatus according to (2), the first gas includes a mixture of a silicon atom-containing gas and a carbon atom-containing gas, and the second gas includes a reducing gas.
(6) In the substrate processing apparatus according to (5), a shielding part configured to suppress a flow of the first gas toward the second gas supply port is not installed at the second gas supply pipe.
(7) In the substrate processing apparatus according to (2), the first gas includes a silicon atom-containing gas and the second gas includes a mixture of a carbon atom-containing gas and a reducing gas.
(8) In the substrate processing apparatus according to (7), the second gas supply pipe further includes second shielding walls installed at both sides of the second gas supply port to expose the second gas supply, the second shielding walls extending from the second gas supply port toward the plurality of substrates.
(9) In the substrate processing apparatus according to any one of (2) to (8), the front end part of the first shielding walls is rounded.
(10) In the substrate processing apparatus according to any one of (2) to (9), the first shielding walls have the same thickness as the first gas supply nozzle.
(11) In the substrate processing apparatus according to any one of (2) to (10), the first gas supply port is installed at the first gas supply pipe in plural, and the first shielding walls is installed to surround the plurality of first gas supply ports.
(12) In the substrate processing apparatus according to any one of (2) to (10), the first gas supply port includes a slit.
(13) In the substrate processing apparatus according to (2), the apparatus further includes a third gas supply pipe configured to form a third gas stream of an inert gas between a first gas stream of the first gas injected from the first gas supply port and a second gas stream of the second gas injected from the second gas supply port.
(14) In the substrate processing apparatus according to (13), the third gas supply pipe includes a third gas supply port configured to supply the inert gas between the first gas supply pipe and the second gas supply pipe.
(15) In the substrate processing apparatus according to (14), the third gas supply port is installed toward a front end part of the first shielding wall.
(16) In the substrate processing apparatus according to (15), the third gas supply port is installed toward the first gas supply port.
(17) In the substrate processing apparatus according to any one of (13) to (16), the first gas includes a silicon atom-containing gas and the second gas includes a carbon atom-containing gas.
(18) In the substrate processing apparatus according to any one of (13) to (16), the first gas includes a mixture of a silicon atom-containing gas and a carbon atom-containing gas, and the second gas includes a reducing gas.
(19) In the substrate processing apparatus according to (2), the second gas supply pipe includes a straight injection part configured to extend from the second gas supply port in an injection direction of the second gas, and a rounded chamfered part installed to surround the injection part, the rounded chamfered part gradually widening from the injection part in the injection direction of the second gas.
(20) In the substrate processing apparatus according to (19), a length of the chamfered part of the second gas supply pipe in an injection direction of the second gas is smaller than a length of the shielding walls of the first gas supply pipe in an injection direction of the first gas.
(21) In addition, the first gas supply pipe or the second gas supply pipe according to any one of (1) to (20) is provided.
(22) According to another aspect of the present invention, there is provided a method of manufacturing a substrate, including: loading into a reaction chamber a plurality of substrates stacked in a boat in a longitudinal direction; supplying a first gas from a first gas supply port included in a first gas supply pipe installed in the reaction chamber along the plurality of substrates loaded into the reaction chamber and a second gas from a second gas supply port included in a second gas supply pipe installed in the reaction chamber along the plurality of substrates loaded into the reaction chamber toward each of the plurality of substrates to form a film on each of the plurality of substrates by mixing of the first gas and the second gas while suppressing a flow of the first gas toward the second gas supply port by a shielding part; and unloading from the reaction chamber the plurality of substrates stacked in the boat having the film formed thereon.
(23) According to still another aspect of the present invention, there is provided a method of manufacturing a semiconductor device, including: loading into a reaction chamber a plurality of substrates stacked in a boat in a longitudinal direction; supplying a first gas from a first gas supply port included in a first gas supply pipe installed in the reaction chamber along the plurality of substrates loaded into the reaction chamber and a second gas from a second gas supply port included in a second gas supply pipe installed in the reaction chamber along the plurality of substrates loaded into the reaction chamber toward each of the plurality of substrates to form a film on each of the plurality of substrates by mixing of the first gas and the second gas while suppressing a flow of the first gas toward the second gas supply port by a shielding part; and unloading from the reaction chamber the plurality of substrates stacked in the boat having the film formed thereon.
(24) According to yet another aspect of the present invention, there is provided a substrate processing apparatus including: a reaction chamber configured to accommodate a plurality of substrates stacked in a longitudinal direction; a heating part installed to surround the reaction chamber and configured to heat the reaction chamber; a first gas supply pipe extending in the longitudinal direction in the reaction chamber, and including a first gas supply port configured to inject a first gas toward the plurality of substrates; a second gas supply pipe extending in the longitudinal direction in the reaction chamber, and including a second gas supply port configured to inject a second gas toward the plurality of substrates; and a third gas supply pipe installed between the first gas supply pipe and the second gas supply pipe to form a third gas stream of an inert gas between a first gas stream of the first gas injected from the first gas supply port and a second gas stream of the second gas injected from the second gas supply port.
(25) In the substrate processing apparatus according to (24), the first gas supply pipe further includes first shielding walls installed at both sides of the first gas supply port to expose the first gas supply port, the first shielding walls extending from the first gas supply port toward the plurality of substrates.
(26) In the substrate processing apparatus according to (24), the second gas supply pipe further includes second shielding walls installed at both sides of the second gas supply port to expose the second gas supply port, the second shielding walls extending from the second gas supply port toward the plurality of substrates.
(27) In the substrate processing apparatus according to (24), the third gas supply pipe includes a third gas supply port installed in the longitudinal direction.
(28) In the substrate processing apparatus according to (24), the first gas includes a silicon atom-containing gas and the second gas includes a carbon atom-containing gas.
(29) In the substrate processing apparatus according to (24), the first gas includes a mixture of a silicon atom-containing gas and a carbon atom-containing gas, and the second gas includes a reducing gas.
(30) In the substrate processing apparatus according to (25), a width of an outer wall of each of the first shielding walls is smaller than that of the first gas supply pipe when the first gas support port is seen in front.
(31) In the substrate processing apparatus according to (25), a distance from a front end part of the first shielding walls to the first gas supply port is greater than a gap between inner walls of the first shielding walls.
(32) In the substrate processing apparatus according to (25), a thickness of each of the first shielding walls is same as that of the first gas supply pipe.
(33) In the substrate processing apparatus according to (25), a plurality of the first gas supply port is installed at the first gas supply pipe, and the first shielding walls are installed to surround the plurality of first gas supply ports.
(34) In the substrate processing apparatus according to (25), the first gas supply port includes a slit.

What is claimed is:

1. A substrate processing apparatus comprising:
a reaction chamber configured to accommodate a plurality of substrates;
a heating part installed to surround the reaction chamber and configured to heat the reaction chamber; and
a first gas supply pipe extending in the reaction chamber,
wherein the first gas supply pipe includes:
a first gas supply port configured to inject a first gas toward the plurality of substrates; and
first shielding walls installed at both sides of the first gas supply port to expose the first gas supply port, the first shielding walls extending toward the plurality of substrates from the first gas supply port.

2. The substrate processing apparatus according to claim 1, further comprising a second gas supply pipe including a second gas supply port configured to inject a second gas toward the plurality of substrates, the second gas supply pipe extending in the reaction chamber.

3. The substrate processing apparatus according to claim 1, wherein a width of an outer wall of each of the first shielding walls is smaller than that of the first gas supply pipe when the first gas supply port is seen from front.

4. The substrate processing apparatus according to claim 1, wherein a distance from a front end part of the first shielding walls to the first gas supply port is greater than a gap between inner walls of the first shielding walls.

5. The substrate processing apparatus according to claim 2, wherein the first gas includes a mixture of a silicon atom-containing gas and a carbon atom-containing gas, and the second gas includes a reducing gas.

6. The substrate processing apparatus according to claim 2, wherein the first gas includes a silicon atom-containing gas and the second gas includes a mixture of a carbon atom-containing gas and a reducing gas.

7. The substrate processing apparatus according to claim 6, wherein the second gas supply pipe further comprises second shielding walls installed at both sides of the second gas supply port to expose the second gas supply port, the second shielding walls extending from the second gas supply port toward the plurality of substrates.

8. The substrate processing apparatus according to claim 1, wherein a plurality of the first gas supply port is installed at the first gas supply pipe, and the first shielding walls are installed to surround the plurality of first gas supply port.

9. The substrate processing apparatus according to claim 1, wherein the first gas supply port comprises a slit.

10. The substrate processing apparatus according to claim 2, further comprising a third gas supply pipe configured to form a third gas stream of an inert gas between a first gas stream of the first gas injected from the first gas supply port and a second gas stream of the second gas injected from the second gas supply port.

11. The substrate processing apparatus according to claim 10, wherein the third gas supply pipe comprises a third gas supply port configured to supply the inert gas between the first gas supply pipe and the second gas supply pipe.

12. The substrate processing apparatus according to claim 11, wherein the third gas supply port is installed toward a front end part of the first shielding wall.

13. The substrate processing apparatus according to claim 11, wherein the third gas supply port is installed toward the first gas supply port.

14. The substrate processing apparatus according to claim 10, wherein the first gas includes a silicon atom-containing gas and the second gas includes a carbon atom-containing gas.

15. The substrate processing apparatus according to claim 10, wherein the first gas includes a mixture of a silicon atom-containing gas and a carbon atom-containing gas, and the second gas includes a reducing gas.

16. The substrate processing apparatus according to claim 2, wherein the second gas supply pipe comprises a straight injection part configured to extend from the second gas supply port in an injection direction of the second gas, and a rounded chamfered part installed to surround the injection part, the rounded chamfered part gradually widening from the injection part in the injection direction of the second gas.

17. A method of manufacturing a substrate, comprising:
loading into a reaction chamber a plurality of substrates stacked in a boat in a longitudinal direction;
supplying a first gas from a first gas supply port included in a first gas supply pipe installed in the reaction chamber along the plurality of substrates loaded into the reaction chamber and a second gas from a second gas supply port included in a second gas supply pipe installed in the reaction chamber along the plurality of substrates loaded into the reaction chamber toward each of the plurality of substrates to form a film on each of the plurality of substrates by mixing of the first gas and the second gas while suppressing a flow of the first gas toward the second gas supply port by a shielding part; and
unloading from the reaction chamber the plurality of substrates stacked in the boat having the film formed thereon.

18. A method of manufacturing a semiconductor device, comprising:
loading into a reaction chamber a plurality of substrates stacked in a boat in a longitudinal direction;
supplying a first gas from a first gas supply port included in a first gas supply pipe installed in the reaction chamber along the plurality of substrates loaded into the reaction chamber and a second gas from a second gas supply port included in a second gas supply pipe installed in the reaction chamber along the plurality of substrates loaded into the reaction chamber toward each of the plurality of substrates to form a film on each of the plurality of substrates by mixing of the first gas and the second gas while suppressing a flow of the first gas toward the second gas supply port by a shielding part; and
unloading from the reaction chamber the plurality of substrates stacked in the boat having the film formed thereon.

19. A substrate processing apparatus comprising:
a reaction chamber configured to accommodate a plurality of substrates stacked in a longitudinal direction;
a heating part installed to surround the reaction chamber and configured to heat the reaction chamber;
a first gas supply pipe extending in the longitudinal direction in the reaction chamber, and including a first gas supply port configured to inject a first gas toward the plurality of substrates;
a second gas supply pipe extending in the longitudinal direction in the reaction chamber, and including a second gas supply port configured to inject a second gas toward the plurality of substrates; and
a third gas supply pipe installed between the first gas supply pipe and the second gas supply pipe to form a third gas stream of an inert gas between a first gas stream of the first gas injected from the first gas supply port and a second gas stream of the second gas injected from the second gas supply port.

20. The substrate processing apparatus according to claim 19, wherein the first gas supply pipe further comprises first shielding walls installed at both sides of the first gas supply port to expose the first gas supply port, the first shielding walls extending from the first gas supply port toward the plurality of substrates.
